(19) United States
(12) Patent Application Publication
(10) Pub. No.: US 2024/0400398 A1
(43) Pub. Date: Dec. 5, 2024

(54) METHOD OF RECYCLING SILICON WASTEWATER AND METHOD OF MANUFACTURING SEMICONDUCTOR BY USING THE SAME

(71) Applicant: Samsung Electronics Co., Ltd., Suwon-si (KR)

(72) Inventors: Myungbeom PARK, Suwon-si (KR); Samjong Choi, Suwon-si (KR); Sungbae Kim, Suwon-si (KR); Jongsoo Kim, Suwon-si (KR); Joonyoung Choi, Suwon-si (KR)

(73) Assignee: Samsung Electronics Co., Ltd., Suwon-si (KR)

(21) Appl. No.: 18/680,657

(22) Filed: May 31, 2024

(30) Foreign Application Priority Data
Jun. 1, 2023 (KR) 10-2023-0071191
Sep. 22, 2023 (KR) 10-2023-0127365

(51) Int. Cl. C01B 33/037; C01B 32/984; C02F 1/44; C02F 11/122; C02F 101/10; C02F 103/34; H01L 29/16; H01M 4/02; H01M 4/587

(52) U.S. Cl. CPC C01B 33/037; C01B 32/984; C02F 1/444; C02F 11/122; H01M 4/587; C01P 2006/40; C02F 2101/10; C02F 2103/346; C02F 2301/046; H01L 29/1608; H01M 2004/027

(57) ABSTRACT

A method of recycling silicon wastewater includes forming a silicon slurry from the silicon wastewater using a micro filtration device, forming a silicone cake from the silicon slurry using a filter press, and forming a silicon powder by drying the silicone cake in a reducing atmospheric.

### CROSS-REFERENCE TO RELATED APPLICATIONS

This application is based on and claims priority under 35 U.S.C. § 119 to Korean Patent Application No. 10-2023-0071191, filed on Jun. 1, 2023, and to Korean Patent Application No. 10-2023-0127365, filed on Sep. 22, 2023, in the Korean Intellectual Property Office, the disclosures of each of which being incorporated by reference herein in their entireties.

### BACKGROUND

Methods consistent with the present disclosure relate to a method of recycling silicon wastewater to recover silicon and a method of manufacturing a semiconductor by using the silicon recovered by the method.

Silicon has been used as a raw material for semiconductor wafers, power semiconductors, solar cells, cathodes, etc. in a wide range of fields such as semiconductors and solar cells. As the use of silicon has increased, measures for reusing silicon included in semiconductor process wastewater have been proposed for the purpose of reducing costs and ensuring the supply of silicon raw materials.

Silicon (Si) raw materials used in the process of manufacturing a semiconductor wafer require high purity (99.999% or higher), and methods to recover high-purity Si while reducing Si wastewater treatment costs have been discussed.

### SUMMARY

It is an aspect to provide a method of recycling silicon wastewater in which costs are reduced and high-purity silicon may be recovered.

It is another aspect to provide a method of manufacturing a semiconductor by using silicon recovered by the method of recycling silicon wastewater, in which costs are reduced and high-purity silicon may be recovered.

According to one or more embodiments, there is provided a method of recycling silicon wastewater, the method comprising forming a silicon slurry from the silicon wastewater by using a micro filtration device; forming a silicone cake from the silicon slurry using a filter press; and forming silicon powder by drying the silicone cake in a reducing atmosphere.

According to one or more embodiments, there is provided a method of recycling silicon wastewater, the method comprising forming a silicone cake by filtering the silicon wastewater; and forming a silicon powder by introducing the silicone cake into a fluidized bed reactor and drying the silicone cake in the fluidized bed reactor using a reducing gas. The fluidized bed reactor comprises a reactor body providing a space in which the silicone cake is fluidized, and a precipitation vessel connected to an upper portion of the reactor body to receive the silicon powder.

According to one or more embodiments, there is provided a method of recycling silicon wastewater, the method comprising separating a first filtrate from the silicon wastewater using a micro filtration filter, and forming a first silicon slurry; separating a second filtrate from the first silicon slurry using a filter press, and forming a first silicone cake; determining whether metal particles are present in the first silicone cake; based on determining that the first silicone cake contains the metal particles, removing the metal particles from the first silicone cake by acid leaching; forming a first mixture by washing a residue of the acid leaching with water; circulating the first mixture back into the micro filtration filter and forming a second silicon slurry; forming a second silicone cake from the second silicon slurry by using the filter press; and forming a silicon powder by drying the second silicone cake under a reducing atmosphere using a fluidized bed reactor.

### BRIEF DESCRIPTION OF THE DRAWINGS

Various embodiments will be more clearly understood from the following detailed description taken in conjunction with the accompanying drawings, in which:

FIG. 1 is a flowchart of a method of recycling silicon wastewater, according to some embodiments;

FIG. 2 is a block diagram of a method of recycling silicon wastewater, according to some embodiments;

FIG. 3 is a diagram illustrating a micro filtration filter according to some embodiments;

FIG. 4 is a cross-sectional view illustrating a filter press according to some embodiments;

FIG. 5 is an enlarged view of a portion indicated by “EX1” in the cross-sectional view of FIG. 4;

FIG. 6 is a cross-sectional view illustrating a fluidized bed reactor according to some embodiments; and

FIG. 7 is a flowchart of a method of recycling silicon wastewater, according to some embodiments.

### DETAILED DESCRIPTION

Hereinafter, various embodiments are described in detail with reference to the accompanying drawings. In the drawings, like reference characters denote like elements, and redundant descriptions thereof are omitted for conciseness.

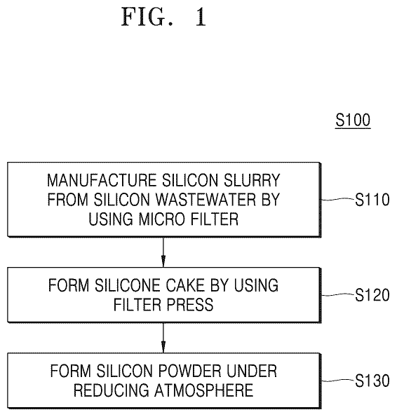

FIG. 1 is a flowchart of a method S100 of recycling silicon wastewater, according to some embodiments.

Referring to FIG. 1, the method S100 of recycling silicon wastewater may include a first operation S110 of forming a silicon slurry from silicon wastewater by using a micro filter, a second operation S120 of forming a silicone cake from the silicon slurry by using a filter press, and a third operation S130 of forming a silicon powder by drying the silicone cake in a reducing atmosphere.

In some embodiments, a specific order of a process may be performed differently from the described order. For example, in some embodiments, two processes described consecutively may be performed substantially at the same time, or may be performed in an order opposite to the described order.

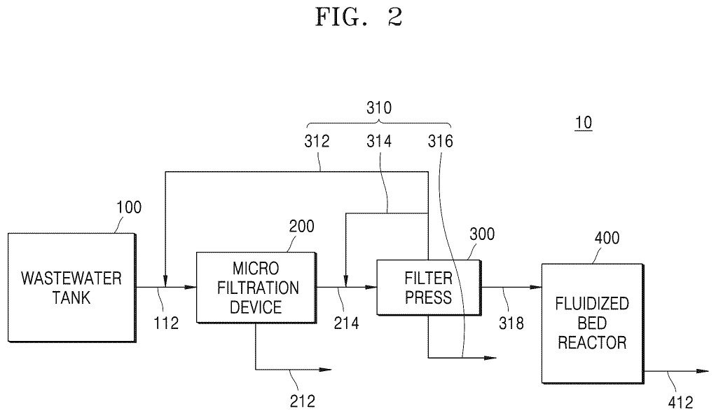

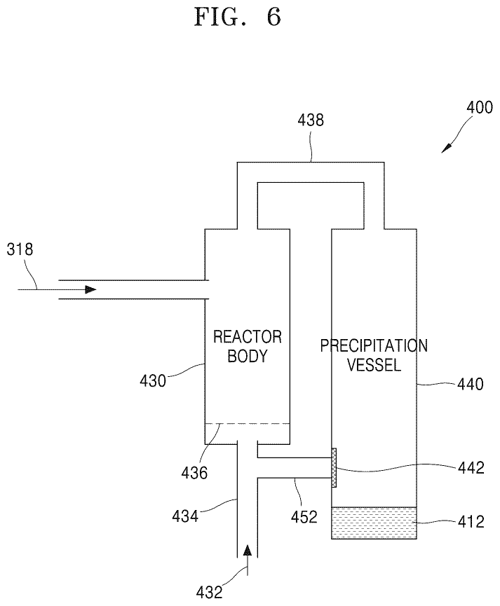

Technical features of the first to third operations S110 to S130 are described in detail below with reference to FIGS. 2 and 6.

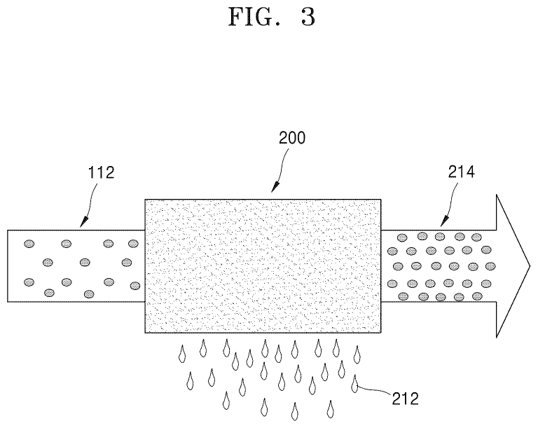

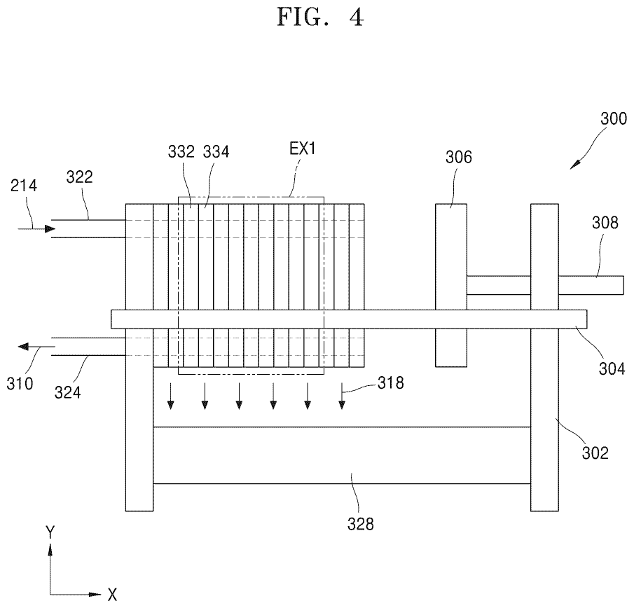

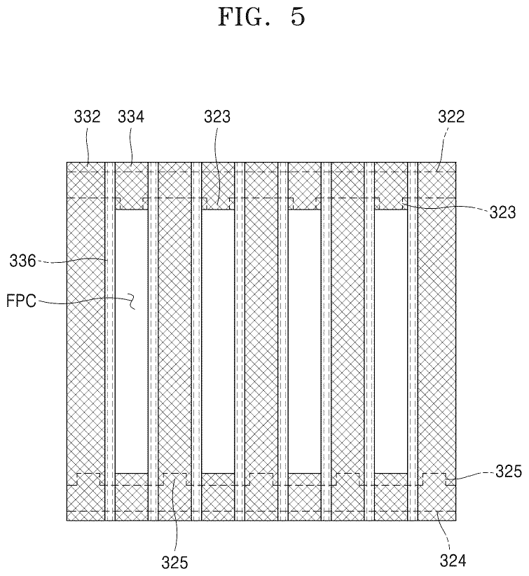

FIG. 2 is a block diagram of a method S100 of recycling silicon wastewater, according to some embodiments. FIG. 3 is a diagram for describing a micro filtration device 200 in the method S100 of FIG. 2, according to some embodiments. FIG. 4 is a cross-sectional view for describing a filter press 300 in the method S100 of FIG. 2, according to some embodiments. FIG. 5 is an enlarged view of a portion indicated by “EX1” in the cross-sectional view of FIG. 4. FIG. 6 is a cross-sectional view illustrating a fluidized bed reactor 400 in the method S100 of FIG. 2, according to some embodiments.

Referring to FIGS. 1 and 2 to 5 together, silicon wastewater generated by a semiconductor manufacturing process may be recovered and stored in a wastewater tank 100.

According to embodiments, the semiconductor manufacturing process may include, for example, a back-lap process for a silicon wafer. For example, the semiconductor manufacturing process may include a back lap process on a rear surface of a silicon wafer for thinning the silicon wafer, a planarization process performed in the semiconductor manufacturing process, a dicing process, etc., but embodiments are not limited thereto, and in some embodiments, various processes that discharge silicon-containing wastewater may be included in the semiconductor manufacturing process.

In some embodiments, the operation of recovering the silicon wastewater may include an operation of uniformly spraying deionized water (hereinafter, “DI water”) on a polishing surface during the polishing process for the silicon wafer. A portion (hereinafter, “silicon particles”) of a silicon wafer removed in the polishing process may be scattered in the form of powder or dust. DI water may be sprayed onto the polishing surface, for example, a surface in contact with a polishing pad, to prevent the silicon particles from scattering, and the silicon particles may be dissolved in the DI water and may be more easily recovered as the silicon wastewater and stored in the wastewater tank 100.

In some embodiments, the silicon particles may include composite particles having a core (Si)-shell (SiO) in which a silicon core is coated with a silicon oxide film. In some embodiments, at least part of the silicon particles scattered in the polishing process may react with DI water and the atmosphere and form a SiO coating film on the surface of the silicon particles. As used in this specification, “SiO” refers to a material including elements included in each term, and is not a chemical formula indicating a stoichiometric relationship.

In some embodiments, a thickness of the SiO coating film may be about 0.01 nm to about 150 nm, but embodiments are not limited to the range of about 0.01 nm to about 150 nm. In some embodiments, the content of the composite particles in the core-shell structure relative to the total weight of the silicon particles may be about 0.01 wt % to 99.99 wt %, but embodiments are not limited to the range of about 0.01 wt % to 99.99 wt %.

According to embodiments described above, the silicon wastewater 112 that is stored in the wastewater tank 100 may be fed into a micro filtration device 220 and silicon slurry 214 may be formed from the silicon wastewater 112 by using the micro filtration device 200, in the first operation S110.

Referring to FIG. 3, the micro filtration device 200 may be configured to separate a first filtrate 212 from the silicon wastewater 112 and form the silicon slurry 214. According to embodiments, the micro filtration device 200 may include a micro filter having a pore size of, for example, less than about 200 nm. For example, in some embodiments, the pore size may be less than about 100 nm. In some embodiments, the pores size may be less than about 50 nm. The micro filter may include a single layer filter, a filter having a multi-layer laminated structure, a membrane filter, or a fiber filter. In some embodiments, the micro filter may include polytetrafluoroethylene (PVDF), fluorinated ethylene propylene (FEP), ethylene tetrafluoroethylene (ETFE), mixed cellulose esters (MCE), cellulose acetate (CA), and/or polytetrafluoroethylene (PTFE), but embodiments not limited thereto.

In some embodiments, the first filtrate 212 may contain materials having small-sized particles, for example, moisture, ions, and/or micro-sized substances, filtered from the silicon wastewater 112 through the micro filtration device 200. In some embodiments, some of the moisture in the silicon wastewater 112 may be removed with the first filtrate 212, and the content (wt %) of silicon particles in the silicon slurry 214 may be higher than the content (wt %) of silicon particles in silicon wastewater 112. In some embodiments, the content of silicon particles relative to the total weight of the silicon slurry 214 may be about 2 wt % to about 35 wt %, but embodiments are not limited thereto.

In some embodiments, the first filtrate 212 may be transported to a purification module (not shown) and reused as process water through a reverse osmosis (RO) process, a deionization process, etc.

Returning to FIG. 2, according to some embodiments, the silicon slurry 214 may be fed into a filter press 300, and a silicone cake 318 may be formed from the silicon slurry 214 by using the filter press 300, in the second operation S120. According to embodiments, the filter press 300 may be configured to separate and recover a second filtrate 310 from the silicon slurry 214 and form the silicone cake 318. In some embodiments, the second filtrate 310 may contain materials having small-sized particles, for example, moisture, ions, and/or micro-sized substances, filtered from the silicon slurry 214 through a filter process of the filter press 300.

As illustrated in FIGS. 4 and 5, according to some embodiments, the filter press 300 may include a press body 302, a press rail 304, a plurality of filter plates 332, a plurality of support frames 334, a plurality of filter cloths 336 (see FIG. 5), a pressure plate 306, and a pressurizing cylinder 308.

In some embodiments, the plurality of filter plates 332 and the plurality of support frames 334 may be alternately arranged in a first horizontal direction (X direction) on the press rail 304, and the plurality of filter cloths 336 may be arranged one-by-one between the plurality of filter plates 332 and the plurality of support frames 334 (see FIG. 5). In some embodiments, the plurality of filter plates 332, the plurality of support frames 334, and the plurality of filter cloths 336 may constitute a filter structure.

In FIG. 5, a vertical cross-section of the plurality of support frames 334 is shown. However, in some embodiments, the plurality of support frames 334 may have a closed loop shape in a plan view. Referring to FIG. 5, each of the plurality of support frames 334 may have a thickness in the first horizontal direction (X direction) and define an internal space. For example, both sidewalls of one support frame 334 in the first horizontal direction (X direction) may each be covered with the filter cloth 336, and accordingly, a filtration chamber FPC may be defined by inner walls of the support frame 334 and the filter cloth 336 covering both sidewalls of the support frame 334. For example, the plurality of filtration chambers FPC may be arranged between each of the plurality of filter plates 332.

In some embodiments, the plurality of filter cloths 336 may be attached onto both sidewalls of each filter plate 332 in the first horizontal direction (X direction). In some embodiments, the plurality of filter cloths 336 may not be attached to each filter plate 332 and may be spaced apart from the filter plate 332 when the filter press 300 is not operated, and may then come into contact with each filter plate 332 when compressed by the pressure plate 306. In some embodiments, the pressure plate 306 is moved by the pressurizing cylinder 308 in the first horizontal direction (X direction) and may be configured to press the filter structure in the horizontal direction (X direction). For example, the pressurizing cylinder 308 may include, but is not limited to, a hydraulic cylinder or a gas cylinder, and various methods and structures for applying pressure to the filter structure may be adopted.

In some embodiments, when the filter press 300 operates, the silicon slurry 214 may be fed into the filter structure, and the filter structure is compressed to define the filtration chamber FPC, and the silicon slurry 214 may be accommodated in the filtration chamber FPC. Thereafter, the second filtrate 310 passing through the filter cloth 336 may be recovered from the silicon slurry 214, and the silicone cake 318 remaining in the filtration chamber FPC may be formed.

In some embodiments, the filter press 300 may include a treatment liquid supply path 322 configured to receive the silicon slurry 214 in the filter structure, and a filtrate recovery path 324 configured to discharge the second filtrate 310 from the filter structure. In some embodiments, a portion of the treatment liquid supply path 322 and a portion of the filtrate recovery path 324 may be formed by compressing the filter structure. For example, each of the plurality of filter plates 332 may include a first through hole, and each of the plurality of support frames 334 may include a second through hole. The first through hole and the second through hole may pass through the filter plate 332 and the support frame 334, respectively, in the first horizontal direction (X direction). For example, when the filtration chamber FPC is formed by compressing the filter structure, the first through hole and the second through hole may be aligned and communicate in the first horizontal direction (X direction), and a plurality of first through holes and a plurality of second through holes may be alternately aligned in the first horizontal direction (X direction) to form a portion of the treatment liquid supply path 322. Similarly, in some embodiments, each of the plurality of filter plates 332 may include a third through hole that is spaced apart from the first through hole, and the plurality of support frames 334 may include a fourth through hole that is spaced apart from the second through hole. When the filtration chamber FPC is formed, the third through hole and the fourth through hole may be aligned and connected in the first horizontal direction (X direction), and a plurality of third through holes and a plurality of fourth through holes may be alternately arranged in the first horizontal direction (X direction) to form a portion of the filtrate recovery path 324.

In some embodiments, each of the plurality of support frames 334 may include therein an inlet port 323 connecting the treatment liquid supply path 322 and the filtration chamber FPC to each other. For example, the inlet port 323 may pass through an inner peripheral wall defining the inner space of each support frame 334 and may be connected to the second through hole of the support frame 334.

In some embodiments, the silicon slurry 214 may be injected from one end of the treatment liquid supply path 322 to fill the plurality of filtration chambers FPC with the silicon slurry 214. The silicon slurry 214 moves in the first horizontal direction (X direction) along the treatment liquid supply path 322 and may branch for each inlet port 323 and fill in each filtration chamber FPC. For example, the silicon slurry 214 may sequentially fill in the plurality of filtration chambers FPC arranged in the first horizontal direction (X direction), for example, from left to right in FIG. 5.

In some embodiments, the silicon slurry 214 in the filtration chamber FPC may be filtered through hydraulic pressure that supplies the silicon slurry 214 to the treatment liquid supply path 322. In some embodiments, the silicon slurry 214 within the filtration chamber FPC may be filtered by the filter cloth 336 by the pressure of the silicon slurry 214 flowing into the filtration chamber FPC through the inlet port 323. For example, the second filtrate 310 may be discharged toward two filter cloths 336 defining the filtration chamber FPC. In some embodiments, the second filtrate 310 may be received and flow into a filtrate channel (not shown) within the plurality of filter plates 332.

In some embodiments, the plurality of filter plates 332 may each include therein a discharge port 325 connecting the filtrate channel (not shown) and the filtrate recovery path 324 to each other. For example, the discharge port 325 may be connected to the filtrate channel (not shown) and the third through hole of each filter plate 332, and the second filtrate 310 may be recovered through the filtrate recovery path 324.

Although not shown, the plurality of filter plates 332 may further include a pressed water channel (not shown) therein. In some embodiments, pressed water may be injected into the pressed water channel (not shown) to expand the plurality of filter plates 332 in the first horizontal direction (X direction) and generate a second filtrate (not shown). For example, even when the plurality of filter plates 332 are expanded, the pressed water may not be connected to the filtration chamber FPC. As a result of pressure being applied to both sidewalls in the first horizontal direction (X direction) of the filtration chamber FPC, the second filtrate 310 passing through the filter cloth 336 may be generated from the silicon slurry 214. The second filtrate 310 may be recovered through the filtrate recovery path 324, as described above. In this case, the pressed water channel (not shown) formed within the plurality of filter plates 332 and the filtrate channel (not shown) described above may be spaced apart and separated from the discharge port 325.

As described above, the second filtrate 310 and the silicone cake 318 may be formed from the silicon slurry 214 by applying pressure to the filtration chamber FPC. In some embodiments, the moisture content (wt %) of the silicone cake 318 may be less than the moisture content (wt %) of the silicon slurry 214. For example, the moisture content (wt %) of the silicone cake 318 may be about 0.1 wt % to about 40 wt % of the total weight of the silicone cake 318, but embodiments are not limited to the range of about 0.1 wt % to about 40 wt %.

In some embodiments, the pressurizing cylinder 308 may move backward to open the plurality of filtration chambers FPC, and the silicone cake 318 may drop into a collection device 328. In some embodiments, the plurality of filter plates 332 and the plurality of support frames 334 may be connected to each other by a chain of a certain length, and as the pressurizing cylinder 308 moves backward, the plurality of filter plates 332 and the plurality of support frames 334 may be spaced apart from each other in the first horizontal direction (X direction) on the rail 304, and the plurality of filtration chambers FPC may be opened. In some embodiments, a method of recovering the silicone cake 318 within the filtration chamber FPC may include, in addition to or in place of dropping of the silicone cake 318 by gravity, a method of having air pressure (not shown) and dropping the silicone cake 318 attached to the plurality of filter cloths 336, or a method of dropping the silicone cake 318 by applying vibration to the plurality of filter cloths 336. However, embodiments are not limited thereto. In some embodiments, the moisture content of the total weight of the silicone cake 318 may be about 1 wt % to about 40 wt %. In some embodiments, the moisture content of the total weight of the silicone cake 318 may be about 5 wt % to about 35 wt %. However, embodiments are not limited to the ranges of about 1 wt % to about 40 wt %, or about 5 wt % to about 35 wt %.

In some embodiments, the plurality of filter cloths 336 may include a multi-membrane including at least one filter paper and at least one coating film. In some embodiments, the filter membrane may have a pore size of about 500 nm to about 1,000 nm. In some embodiments, the coating membrane may have a smaller pore size than the filter membrane. For example, the plurality of filter cloths 336 may be composed of a multi-membrane including a filter paper and a coating film and may filter silicon particles in the silicon slurry 214 having a very small particle size.

In some embodiments, the filter paper may include at least one selected from the group consisting of polyimide, polypropylene, polyester, polycarbonate, polyethylene, polyethylene terephthalate, polybutylene terephthalate, polyethylene naphthalate, and polybutylene naphthalate, but embodiments are not limited thereto. In some embodiments, the coating film may include cellulose-based polymer, but embodiments are not limited thereto.

Referring back to FIG. 2, in some embodiments, some of the second filtrate 310 may be circulated back to the front end of a process according to the method S100 of recycling silicon wastewater. In some embodiments, the second filtrate 310 may include a third filtrate 312 and a fourth filtrate 314, and the third filtrate 312 and the fourth filtrate 314 may each be circulated back to the front end of the process as all or part of the second filtrate 310.

In some embodiments, the third filtrate 312 may be circulated back and fed into the micro filtration device 200 for the operation of forming the silicon slurry 214 from the silicon wastewater 112. In some embodiments, the third filtrate 312 may be circulated back into the wastewater tank 100. In some embodiments, the third filtrate 312 circulated back and may be included in the silicon wastewater 112 introduced into the micro filtration device 200. In some embodiments, the third filtrate 312 may not be included in the silicon wastewater 112, but may be separately recovered and introduced into the micro filtration device 200. For example, a portion of the second filtrate 310 may be circulated back and fed into the micro filtration device 200.

In some embodiments, the fourth filtrate 314 may be circulated back and fed into the filter press 300 for the second operation S120 of forming the silicone cake 318 from the silicon slurry 214. For example, all or part of the second filtrate 310 recovered in the process of forming the silicone cake 318 may be circulated back and fed into the filter structure of the filter press 300 through the treatment liquid supply path 322.

In some embodiments, the second filtrate 310 may include a fifth filtrate 316 that is transported to the purification module (not shown). For example, the fifth filtrate 316 may be stored in a buffer tank (not shown) together with the first filtrate 212 recovered through the micro filtration device 200, and then reused as process water through an RO process and a deionization process.

In some embodiments, in the second filtrate 310 discharged in the process of forming the silicone cake 318, according to the order of discharge, a first portion that is discharged first may be circulated back to the front end of the process (i.e., to the micro filtration device 200), and a second portion that is discharged later than the first portion may be recovered and reused as process water. For example, in the second filtrate 310, a first portion that is discharged temporally earlier may be circulated back and fed into the micro filtration device 200 or fed back into the filter press 300, and second portion that is discharged temporarily later than the first portion may be recovered and reused.

For example, the operation of recovering the second filtrate 310 from the silicon slurry 214 may include circulating back the third filtrate 312 and the fourth filtrate 314 and then recovering the fifth filtrate 316. The second filtrate 310 may be classified according to an order in which the second filtrate 310 is discharged through the filtrate recovery path 324 during the process of compressing the filtration chamber FPC. For example, in some embodiments, the third filtrate 312 and the fourth filtrate 314 of the second filtrate 310 may be discharged at the beginning of compression, and then, the fifth filtrate 316 may be discharged. In some embodiments, the content (wt %) of silicon particles in the third filtrate 312 may be a first content, and the content (wt %) of silicon particles in the fourth filtrate 314 may be a second content. The content (wt %) of silicon particles in the fifth filtrate 316 may be a third content. In some embodiments, each of the first content and the second content may be greater than the third content. At the beginning of the filter press operation, some silicon particles smaller than the pore size of the filter cloth 336 may be included in the third filtrate 312 and the fourth filtrate 314 and discharged. As the compression progresses, the pores of the filter cloth 336 may be partially blocked by silicon particles or a collection of silicon particles larger than the pores, and accordingly, in the fifth filtrate 316 discharged from the rear end of the filter structure, silicon particles may be included in a relatively lower content than the content in the third filtrate 312 and the fourth filtrate 314. Accordingly, the third filtrate 312 and/or the fourth filtrate 314, which have a relatively high silicon particle content, may be circulated at the front end of the process and inserted into the silicon wastewater 112 or into the silicon slurry 214, and silicon particles in the third filtrate 312 and/or fourth filtrate 314 may be repeatedly filtered. In some embodiments, the fifth filtrate 316, which has a relatively small content of silicon particles, that is, from which silicon particles have been sufficiently removed, may be recovered and reused. In some embodiments, a concentration of silicon particles in the fifth filtrate 316 may be about 0.1 ppm to about 50 ppm. For example, the concentration of silicon particles in the fifth filtrate 316 may be about 10 ppm or less. But, these concentrations are only examples and embodiments are not limited thereto.

In some embodiments, the operation of recovering the second filtrate 310 from the silicon slurry 214 may further include an operation of analyzing components of the second filtrate 310. In some embodiments, the components of the second filtrate 310 may be analyzed in real time during the process of compressing the silicon slurry 214. By analyzing the concentration/content of silicon particles in the second filtrate 310, it may be determined whether to circulate the second filtrate 310 to the front end of the process or to recover the filtrate as process water.

As described above, the content (wt %) of silicon particles in the second filtrate 310 at the beginning of compression of the silicon slurry 214 may be relatively high and may be lowered depending on the compression process. In some embodiments, the fourth filtrate 314 discharged at the time of initial compression may be circulated back and introduced back into the filter press 300. The third filtrate 312, which is discharged thereafter and has a relatively lower silicon particle content (wt %) than the fourth filtrate 314, may be circulated back and introduced back into the micro filtration device 200. The fifth filtrate 316, which has a lower silicon particle content (wt %) than the third filtrate 312, may be purified and recovered as process water.

Returning to FIG. 2, according to some embodiments, a silicon powder 412 may be formed by drying the silicone cake 318, in the third operation S130. The silicone cake 318 may be introduced into the fluidized bed reactor 400 and dried under a reducing atmosphere to form the silicon powder 412.

As illustrated in FIG. 6, according to some embodiments, the fluidized bed reactor 400 may include a reactor body 430, a gas injection pipe 434, a distribution plate 436, a first gas circulation pipe 438, a precipitation vessel 440, and a second gas circulation pipe 452.

According to embodiments, the silicone cake 318 may be injected into an upper portion of the reactor body 430, and a reducing gas 432 may be injected into a lower portion of the reactor body 430 to fluidize the silicone cake 318 within the reactor body 430. For example, the silicone cake 318 may fall toward the lower portion by gravity, and the reducing gas 432 may be sprayed from the lower portion toward the upper portion, so that the falling silicone cake 318 may be fluidized by an upward air current.

In some embodiments, the reducing gas 432 may be dispersed into a reaction space within the reactor body 430 through the distribution plate 436 arranged at the bottom of the reactor body 430. The reaction space may be defined as a space in which the silicone cake 318 is fluidized. In some embodiments, the reducing gas 432 injected into the reactor body 430 may be uniformly dispersed into the reaction space through the distribution plate 436, and the silicone cake 318 or reaction products may be prevented from falling to the bottom of the reactor body 430 and blocking the gas injection pipe 434.

In some embodiments, the reducing gas 432 may include hydrogen (H₂). In some embodiments, some of the silicon particles in the silicone cake 318 may have a structure in which a silicon core is coated with a silicon oxide (SiO) film. The SiO film may generate silicon (Si) and moisture (H₂O) through a reduction reaction with H₂. According to the method S100 of recycling silicon wastewater, according to some embodiments, silicon particles coated with a SiO film or silicon grains including silicon oxide may be reduced to Si to obtain Si in a pure raw material state.

In some embodiments, the reducing gas 432 may further include an inert gas. In some embodiments, the inert gas may include at least one selected from the group consisting of argon (Ar), helium (He), nitrogen (N₂), neon (Ne), krypton (Kr), and xenon (Xe).

In some embodiments, the reactor body 430 may be heated to evaporate moisture in the silicone cake 318 and promote a reduction reaction of the SiO film. In some embodiments, a temperature inside the reactor body 430 may be maintained at about 250° C. to about 800° C. In some embodiments, the reducing gas 432 may be injected under high temperature conditions having the temperature range of about 250° C. to about 800° C.

In some embodiments, the fluidized silicone cake 318 may include silicon clusters and individual silicon particles agglomerated by moisture. The individual silicon particles may include first particles with a relatively small diameter and second particles with a relatively larger diameter than the first particles. For example, in some embodiments, the first particles may have a diameter of about 50 nm to about 250 nm. In some embodiments, the first particles may have a diameter of about 100 nm to about 200 nm.

In some embodiments, immediately after the silicone cake 318 is fluidized, the content (wt %) of the silicon clusters in the fluidized silicone cake 318 may be higher than the content (wt %) of the individual silicon particles. The silicon clusters may repeatedly fall by gravity and rise by the reducing gas 432, lose moisture under high temperature and reducing atmosphere, and may be disposed into individual silicon particles. In some embodiments, the moisture in the fluidized silicone cake 318 may gradually evaporate, the relatively light first particles may be scattered to the upper portion of the reactor body 430 by the upward air current, and the relatively heavy second particles may descend and be deposited on the upper surface of the distribution plate 436, or may remain in the reaction space in a fluidized state. In some embodiments, the first particles may be introduced into the precipitation vessel 440 through the first gas circulation pipe 438 connecting the reactor body 430 and the precipitation vessel 440 to each other. For example, the first gas circulation pipe 438 may be connected to the upper portion of the reactor body 430 and the upper portion of the precipitation vessel 440, and the first particles may pass through the first gas circulation pipe 438 and flow into the precipitation vessel 440.

In some embodiments, the first particles may descend within the precipitation vessel 440 and settle on a lower side of the precipitation vessel 440. In some embodiments, compared to the reactor body 430, there may be no upward air current within the precipitation vessel 440. In some embodiments, there may be only a relatively small upward air current derived from circulation within the precipitation vessel 440, and the first particles may fall by gravity and be deposited under the precipitation vessel 440 to form the silicon powder 412. In some embodiments, the silicon powder 412 may be composed of first particles having a relatively small and uniformly sized diameter. For example, in the silicone cake 318 introduced into the fluidized bed reactor 400, SiO may be reduced, and the second particles, which are relatively heavy and have a large diameter, may remain in the reactor body 430 and be separated, and the silicon powder 412 recovered from the precipitation vessel 440 may include high-purity silicon particles of uniform size. The method S100 of recycling silicon wastewater, according to embodiments, may include efficiently recovering silicon particles of uniform size by using the upward air current of the reducing gas 432 used in the process of removing impurities and moisture from the silicone cake 318 without a separate process for classifying silicon particles according to size.

In some embodiments, the reducing gas 432 introduced into the precipitation vessel 440 may be circulated through the second gas circulation pipe 452 back into the gas injection pipe 434 and reintroduced into the reactor body 430 and reused. In some embodiments, the fluidized bed reactor 400 may further include a dust collection filter 442 provided at the inlet of the gas injection pipe 434 on the side of the precipitation vessel 440. In some embodiments, the dust collection filter 442 may prevent the second particles introduced into the precipitation vessel 440, that is, the silicon powder 412, from flowing into the second gas circulation pipe 452 together with the reducing gas 432. In other words, the dust collection filter 442 may be configured to filter the silicon powder 412, and in the method S100 of recycling silicon wastewater, according to embodiments, process costs may be reduced by circulating and reusing the reducing gas 432.

Although not shown, the fluidized bed reactor 400 may further include a moisture removal filter (not shown) provided in the second gas circulation pipe 452. SiO of the silicone cake 318 may be reduced under a reducing atmosphere to generate H₂O, and the generated H₂O and moisture in the silicone cake 318 may be evaporated in the reactor body 430 at a high-temperature. Accordingly, water vapor may be included in the reducing gas 432 and introduced into the precipitation vessel 440. In some embodiments, the water vapor in the precipitation vessel 440 may be removed by flowing into the second gas circulation pipe 452 together with the reducing gas 432, and the reducing gas 432 from which the water vapor is removed may enter the gas injection pipe 434 and may be re-introduced into the reactor body 430 in a dry state.

In some embodiments, the recovered silicon powder 412 may be used as a raw material for semiconductor wafers, power semiconductors, solar electricity, anode agents, etc., but embodiments are not limited thereto.

In some embodiments, the silicon powder 412 may be vaporized to form an ingot for manufacturing a semiconductor wafer. For example, a silicon solution prepared from the silicon powder 412 may be put into a casting and rotated to grow silicon crystals to form an ingot. For example, the Czochralski method (CZ) or the floating zone method (FZ) may be used as a growth method for silicon crystals.

In some embodiments, the silicon powder 412 may be carbonized under a reactive gas containing a carbon source to form silicon carbide (SiC). For example, the carbon source may include methane (CH₄). The SiC may be used, for example, to manufacture power semiconductor wafers.

In some embodiments, the silicon powder 412 may be mixed with graphite (C) powder to form an anode material for manufacturing a secondary battery. The anode material may include SiC, and a secondary battery may be manufactured by using the anode material.

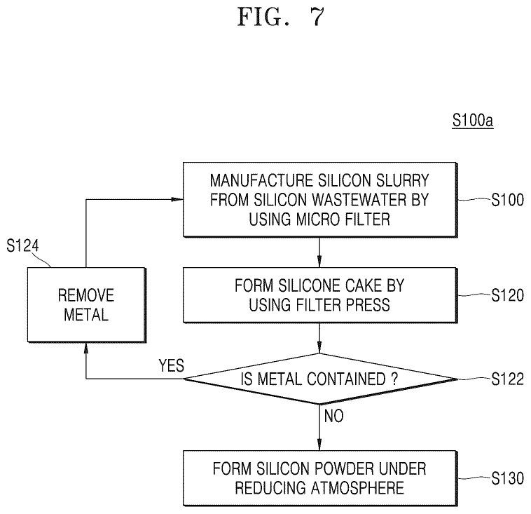

FIG. 7 is a flowchart of a method S100a of recycling silicon wastewater, according to some embodiments. In FIG. 7, the same reference characters as those of FIG. 1 denote the same process. The method S100a of recycling silicon wastewater, described below, is described with reference to FIGS. 2 to 6 together, and redundant descriptions of the members and processes described with reference to FIGS. 1 to 6 are omitted for conciseness. The difference between the method S100a of recycling silicon wastewater, described with reference to FIG. 7, and the method S100 of recycling silicon wastewater, described above with reference to FIG. 1 is whether operation S122 of determining whether metal is contained in the silicone cake 318 and operation S124 of removing the metal are further included.

In some embodiments, the silicone cake 318 may include metal particles. For example, a semiconductor process that discharges the silicon wastewater may include not only a rear surface polishing process of a silicon wafer for manufacturing a semiconductor wafer, but also a dicing process, a planarization process of a semiconductor chip, etc., and thus, the silicon wastewater 112, the silicon slurry 214, and the silicone cake 318 may include metal particles.

According to embodiments, the method S100a of recycling silicon wastewater may include determining S122 whether metal is contained in the silicone cake 318 in operation S122, and when it is determined that the metal is contained (S122, YES), removing the metal in operation S124.

In some embodiments, after forming the silicon cake 318 from the silicon slurry 214, components of the silicone cake 318 may be analyzed to determine whether the silicone cake 318 contains metal particles. In some embodiments, the presence or absence of metal particles may be determined at the front end of the process before the operation of manufacturing the silicone cake 318. For example, it may be first determined whether metal particles are contained in the silicon wastewater 112 or the silicon slurry 214. In this case as well, metal removal S124 may be performed after the silicone cake 318 is formed.

In some embodiments, when the analysis results show that the silicone cake 318 contains metal particles, the metal particles in the silicone cake 318 may be removed by leaching with an acidic solution, and the precipitated residue from the leaching may be washed with water.

In some embodiments, the acidic solution may include at least one selected from the group consisting of hydrochloric acid (HCl), nitric acid (HNO₃), sulfuric acid (H₂SO₄), and hydrofluoric acid (HF). The silicone cake 318 may be treated with the acidic solution to leach metal particles. The precipitated silicon particles may be recovered and repeatedly washed with water to obtain a first mixture containing H₂O and silicon containing H₂O and silicon particles.

In some embodiments, the first mixture may be circulated to the front end of a silicon recycling process according to embodiments described above. For example, the silicon slurry 214 may be formed from the first mixture by feeding the first mixture back into the micro filtration device 200 and using the micro filtration device 200, and the silicone cake 318 may be formed from the silicon slurry 214 by using the filter press 300. For example, because the first mixture is a solution obtained by removing metal particles, the silicone cake 318 obtained from the first mixture may not contain metal particles. Thereafter, the silicone cake 318 may be dried under a reducing atmosphere to recover high-purity, uniformly sized silicon particles obtained by removing metal particles.

In some embodiments, when the content of silicon particles in the first mixture is relatively higher than moisture, for example, the content of silicon particles in the first mixture is about 2 wt % to about 35 wt % based on the total weight of the first mixture, the first mixture may be circulated to the filter press 300 instead of the micro filtration device 200. For example, the first mixture may be circulated back into the silicon slurry 214 formation operation or the silicone cake 318 formation operation, depending on the concentration/content of silicon particles in the first mixture.

In some embodiments, it may be analyzed whether the silicone cake 318 contains metal particles, in operation S122, and when it is identified as a result of the analysis that metal particles are not present in the silicone cake 318 or are contained below a reference value (operation S122, NO), the silicone cake 318 may be dried under a reducing atmosphere to form the silicon powder 412, similar to the method S100 of recycling silicon wastewater, described with reference to FIG. 6.

While various embodiments have been particularly shown and described with reference to the drawings, it will be understood that various changes in form and details may be made therein without departing from the spirit and scope of the following claims.

What is claimed is:

1. A method of recycling silicon wastewater, the method comprising:
forming a silicon slurry from the silicon wastewater by using a micro filtration device;
forming a silicone cake from the silicon slurry using a filter press; and
forming silicon powder by drying the silicone cake in a reducing atmosphere.

2. The method of claim 1, wherein forming the silicon slurry comprises recovering and reusing a first filtrate separated from the silicon wastewater by the micro filtration device.

3. The method of claim 1, wherein forming the silicone cake comprises circulating a second filtrate that has been separated from the silicon slurry by the filter press back into the micro filtration device.

4. The method of claim 1, wherein forming the silicone cake comprises circulating a second filtrate that has been separated from the silicon slurry by the filter press back into the filter press.

5. The method of claim 1, wherein forming the silicone cake comprises separating a second filtrate from the silicon slurry,
in the second filtrate, a first portion separated temporally first is circulated back to the micro filtration device, and
in the second filtrate, a second portion separated temporally later than the first portion is recovered and reused.

6. The method of claim 1, wherein forming the silicon powder comprises fluidizing the silicone cake using a reducing gas in a fluidized bed reactor.

7. The method of claim 6, wherein the reducing gas comprises hydrogen.

8. The method of claim 6, wherein the fluidized bed reactor comprises a reactor body and a precipitation vessel, an upper portion of the reactor body and an upper portion of the precipitation vessel are connected to each other,
wherein the forming of the silicon powder comprises injecting the reducing gas from a lower portion of the reactor body toward the upper portion of the reactor body, and
wherein a dried portion of the silicone cake moves from the upper portion of the reactor body to the precipitation vessel by an upward air current of the reducing gas to form the silicon powder.

9. The method of claim 1, further comprising:
after forming the silicone cake, determining whether metal particles are present in the silicone cake;
based on determining that the silicone cake contains the metal particles, removing the metal particles from the silicon cake by acid leaching; and
forming a first mixture by washing a residue of the acid leaching with water.

10. The method of claim 9, further comprising circulating the first mixture back into the micro filtration device.

11. A method of recycling silicon wastewater, the method comprising:
forming a silicone cake by filtering the silicon wastewater; and
forming a silicon powder by introducing the silicone cake into a fluidized bed reactor and drying the silicone cake in the fluidized bed reactor using a reducing gas,
wherein the fluidized bed reactor comprises a reactor body providing a space in which the silicone cake is fluidized, and a precipitation vessel connected to an upper portion of the reactor body to receive the silicon powder.

12. The method of claim 11, wherein drying the silicone cake is performed at a temperature range of about 250° C. to about 800° C.

13. The method of claim 11, wherein forming the silicon powder comprises:
injecting the reducing gas from a lower portion of the reactor body to the upper portion of the reactor body to move the reducing gas to the precipitation vessel; and
circulating the reducing gas in the precipitation vessel and reintroducing the circulated gas from the precipitation vessel back into the reactor body.

14. The method of claim 13, wherein the reducing gas in the precipitation vessel comprises water vapor formed from the silicone cake, and
circulating the reducing gas in the precipitation vessel comprises removing the water vapor.

15. The method of claim 11, further comprising manufacturing a semiconductor wafer using the silicon powder.

16. The method of claim 11, further comprising:
forming silicon carbide (SiC) by carbonizing the silicon powder; and
manufacturing a power semiconductor wafer from the SiC.

17. A method of recycling silicon wastewater, the method comprising:
separating a first filtrate from the silicon wastewater using a micro filtration filter, and forming a first silicon slurry;
separating a second filtrate from the first silicon slurry using a filter press, and forming a first silicone cake;
determining whether metal particles are present in the first silicone cake;
based on determining that the first silicone cake contains the metal particles, removing the metal particles from the first silicone cake by acid leaching;
forming a first mixture by washing a residue of the acid leaching with water;
circulating the first mixture back into the micro filtration filter and forming a second silicon slurry;
forming a second silicone cake from the second silicon slurry by using the filter press; and
forming a silicon powder by drying the second silicone cake under a reducing atmosphere using a fluidized bed reactor.

18. The method of claim 17, wherein, in the second filtrate, a first portion separated temporally first is circulated back to the micro filtration filter, and
in the second filtrate, a second portion separated temporally later than the first portion is recovered and reused.

19. The method of claim 17, further comprising forming an anode material for manufacturing a secondary battery using the silicon powder.

20. The method of claim 19, further comprising manufacturing the secondary battery using the anode material,
wherein forming the anode material comprises forming silicon carbide by mixing the silicon powder with graphite.
